(19) United States
(12) Patent Application Publication
(10) Pub. No.: US 2018/0135183 A1
(43) Pub. Date: May 17, 2018

(54) Surface Treatment For EUV Lithography

(71) Applicant: Applied Materials, Inc., Santa Clara, CA (US)

(72) Inventors: Weimin Zeng, San Jose, CA (US); Yong Cao, San Jose, CA (US); Daniel Lee Diehl, Mihama-ku Chiba (JP); Khoi Phan, San Jose, CA (US); Huixiong Dai, San Jose, CA (US); Christopher S. Ngai, Burlingame, CA (US)

(21) Appl. No.: 15/806,500

(22) Filed: Nov. 8, 2017

Related U.S. Application Data
(60) Provisional application No. 62/421,345, filed on Nov. 13, 2016.

(51) Int. Cl. C23C 16/56; C23C 16/455; G03F 1/22

(52) U.S. Cl. CPC C23C 16/56; G03F 1/22; C23C 16/455

(57) ABSTRACT

Processing methods comprising depositing an initial hardmask film on a substrate by physical vapor deposition and exposing the initial hardmask film to a treatment plasma comprising a silane compound to form the hardmask.

### CROSS-REFERENCE TO RELATED APPLICATIONS

This application claims priority to U.S. Provisional Application No. 62/421,345, filed Nov. 13, 2016, the entire disclosure of which is hereby incorporated by reference herein.

### TECHNICAL FIELD

The present disclosure relates generally to methods of forming EUV photoresists. In particular, the disclosure relates to methods to form EUV photoresists with treatment to increase adhesion.

### BACKGROUND

Photolithography employs photoresists, which are photosensitive films, for transfer of negative or positive images onto a substrate, e.g., a semiconductor wafer. Subsequent to coating a substrate with a photoresist, the coated substrate is exposed to a source of activating radiation, which causes a chemical transformation in the exposed areas of the surface. The photo-resist coated substrate is then treated with a developer solution to dissolve or otherwise remove either the radiation-exposed or unexposed areas of the coated substrate, depending on the type of photoresist employed.

Lithographic techniques for creation of features having sizes of thirty nanometers or less, however, suffer from a number of shortcomings. For example, line width variations of a resist film produced by such techniques can be too large to be acceptable in view of tightening dimensional tolerances typically required in this range, e.g., tolerances of the order of the scales of the molecular components of the resist film. Such linewidth variations may be classified as line edge roughness (LER) and/or line width roughness (LWR).

Line edge roughness and line width roughness reflect linewidth fluctuations that may lead to variations in device characteristics. As critical dimensions for integrated circuits continued to shrink, linewidth fluctuations will play an increasingly significant role in critical dimensions (CD) error budget for lithography. Several suspected sources of LER and LWR in resist patterns include the reticle quality, the aerial image quality, and resist material properties.

Physical vapor deposition (PVD) processes can be used to deposit or form the photoresist materials on a substrate. However, not all PVD films have sufficient surface adhesion to act as a photoresist. Generally, wetting angles should be greater than or equal to about 60°-70° to be effective photoresists. The wetting angle of PVD deposited films are generally too low (e.g., 5° to 25°) to provide useful films.

Therefore, there is a need for methods of forming photoresist materials with high wetting angles. Additionally, there is a need in the art form photoresist materials that allow sufficient throughput during processing.

### SUMMARY

One or more embodiments of the disclosure are directed to methods of forming a hardmask. The methods comprise depositing an initial hardmask film on a substrate by physical vapor deposition. The initial hardmask film is exposed to a treatment plasma comprising a silane compound to form the hardmask.

Additional embodiments of the disclosure are directed to methods of forming a hardmask. A substrate is positioned in a physical vapor deposition chamber. An initial hardmask film is formed on the substrate by physical vapor deposition. The initial hardmask film comprises one or more of AlO, SiN, a-Si, SiOC, SiON, AlON or AlN. The substrate is moved from the physical vapor deposition chamber to a chemical vapor deposition chamber. The initial hardmask film is exposed to a treatment plasma comprising a silane compound and an inert gas to form the hardmask.

Further embodiments are directed to methods of forming a hardmask. A substrate is positioned in a physical vapor deposition chamber. In the the range of about 5 nm to about 20 nm of an initial hardmask film is deposited on the substrate by physical vapor deposition. The initial hardmask film comprises one or more of AlO, SiN, a-Si, SiOC, SiON, AlON or AlN. The substrate is moved from the physical vapor deposition chamber to a chemical vapor deposition chamber. The initial hardmask film is exposed to a treatment plasma to form the hardmask in the chemical vapor deposition chamber. The treatment plasma comprises a silane compound and an inert gas in a ratio of about 0.1 to about 20% on an atomic basis. The treatment plasma has a pressure in the range of about 1 Torr to about 5 Torr, a power in the range of about 50 W to about 200 W and is exposed for a time in the range of about 2 second to about 10 seconds. The hardmask has a wetting angle greater than or equal to about 60°.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure are directed to methods to develop new physical vapor deposited films for next generation lithography applications. Not all PVD films have enough surface adhesion to act as a suitable photoresist. The inventors have developed a surface treatment using silane gas in a chemical vapor deposition chamber to treat all PVD films. The surface treatment can improve the wetting angle and the photoresist adhesion and minimize or prevent line bending during post-processing.

Some embodiments provide surface treatment PVD films which allow for a reduction of about 15 to about 40 percent in dosage of the photoresist. The dose is the amount of energy that is used to print the mask on the wafer. The decrease in dosage can increase the wafer throughput during processing.

Accordingly, one or more embodiments of the disclosure form a hardmask. An initial hardmask is deposited on a substrate surface by physical vapor deposition. The initial hardmask of some embodiments comprises one or more of AlO, SiN, a-Si, SiOC, SiON, AlON or AlN.

The thickness of the initial hardmask film can be any suitable thickness. In some embodiments, the thickness of the initial hardmask film is in the range of about 3 nm to about 25 nm, or in the range of about 5 nm to about 20 nm, or in the range of about 5 nm to about 10 nm. In some embodiments, the thickness of the initial hardmask remains substantially the same (i.e., within ±10%) after exposure to a treatment plasma. In some embodiments, the thickness of the initial hardmask changes after exposure to a treatment plasma.

After formation of the initial hardmask film, the substrate is exposed to a treatment plasma to form the hardmask. In some embodiments, the substrate is moved from the physical vapor deposition chamber to a separate chamber for treatment. In one or more embodiments, the separate chamber is a chemical vapor deposition chamber.

In some embodiments, the treatment plasma comprises a silane compound. In one or more embodiments, the silane compound comprises one or more of silane, disilane, trisilane, tetrasilane, higher order silanes or substituted silanes. As used in this regard, the term “higher order silanes” means a silane compound with five or more silicon atoms. A substituted silane is a silane compound with organic or halogen substituents. In some embodiments, the organic substituents comprise a C1-C6 alkyl group.

The treatment plasma can comprise any suitable compound that can increase the wetting angle of the initial hardmask film to an amount greater than or equal to about 60°. In one or more embodiments, treatment of the initial hardmask film forms a hardmask with a wetting angle greater than or equal to about 60°. In some embodiments, the wetting angle of the hardmask is greater than or equal to about 70°, 80° or 90°.

The plasma conditions including pressure, power, frequency and exposure time can be controlled to raise the wetting angle. In some embodiments, the treatment plasma has a pressure in the range of about 1 mTorr to about 10 Torr. In some embodiments, the treatment plasma has a pressure in the range of about 100 mTorr to about 10 Torr, or in the range of about 1 Torr to about 10 Torr, or in the range of about 2 Torr to about 5 Torr, or about 3 Torr.

The treatment plasma can be generated with any suitable power. In some embodiments, the power is in the range of about 50 W to about 500 W, or in the range of about 50 W to about 200 W, or about 100 W.

The exposure time to the plasma treatment can be any suitable exposure time. A shorter exposure time may have a smaller impact on overall substrate processing throughput. A longer exposure time may increase the wetting angle by a larger amount. In some embodiments, the exposure time is a balance between increasing the wetting angle and minimizing impact on the throughput. In one or more embodiments, the plasma treatment occurs for a time in the range of about 1 second to about 100 seconds. In some embodiments, the plasma treatment occurs for a time in the range of about 2 seconds to about 10 seconds, or in the range of about 3 seconds to about 7 seconds, or about 5 seconds.

The treatment plasma of some embodiments further comprises an inert gas. The inert gas can be any suitable inert gas including, but not limited to, argon, helium, neon or krypton. In some embodiments, the inert gas comprises substantially only argon. As used in this manner, “substantially only” means that the inert gas component of the plasma treatment is greater than or equal to about 95% of the stated component on an atomic basis.

The ratio of the silane to the inert gas can be any suitable ratio. In some embodiments, the plasma treatment has a silane compound to inert gas ratio in the range of about 1:1000 to about 2:10. Stated differently, the silane to inert gas ratio is in the range of about 0.1% to about 20% on an atomic basis. In some embodiments, the silane to inert gas ratio is about 1:100, or about 1% on an atomic basis.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming a hardmask, the method comprising:
depositing an initial hardmask film on a substrate by physical vapor deposition; and
exposing the initial hardmask film to a treatment plasma comprising a silane compound to form the hardmask.

2. The method of claim 1, wherein the hardmask has a wetting angle greater than or equal to about 60°.

3. The method of claim 1, further comprising moving the substrate from a physical vapor deposition chamber to a chemical vapor deposition chamber between depositing the initial hardmask film and treating the hardmask film.

4. The method of claim 1, wherein the initial hardmask film comprises one or more of AlO, SiN, a-Si, SiOC, SiON, AlON or AlN.

5. The method of claim 1, wherein the initial hardmask film is formed to a thickness in the range of about 5 nm to about 20 nm.

6. The method of claim 1, wherein the silane compound comprises one or more of silane, disilane, trisilane, tetrasilane, higher order silanes or substituted silanes.

7. The method of claim 1, wherein the treatment plasma has a pressure in the range of about 1 mTorr to about 10 Torr.

8. The method of claim 1, wherein the treatment plasma has pressure in the range of about 1 Torr to about 5 Torr.

9. The method of claim 1, wherein the plasma treatment has a power in the range of about 50 W to about 500 W.

10. The method of claim 1, wherein the plasma treatment has a power in the range of about 50 W to about 200 W.

11. The method of claim 1, wherein the plasma treatment occurs for a time in the range of about 1 second to about 100 seconds.

12. The method of claim 1, wherein the plasma treatment occurs for a time in the range of about 2 seconds to about 10 seconds.

13. The method of claim 1, wherein the plasma treatment comprises the silane compound in an inert gas comprising one or more of Ar, He, Ne or Kr.

14. The method of claim 13, wherein the plasma treatment has a silane compound to inert gas ratio in the range of about 1:1000 to about 2:10.

15. A method of forming a hardmask, the method comprising:
positioning a substrate in a physical vapor deposition chamber;
forming an initial hardmask film on the substrate by physical vapor deposition, the initial hardmask film comprising one or more of AlO, SiN, a-Si, SiOC, SiON, AlON or AlN;
moving the substrate from the physical vapor deposition chamber to a chemical vapor deposition chamber; and
exposing the initial hardmask film to a treatment plasma comprising a silane compound and an inert gas to form the hardmask.

16. The method of claim 15, wherein the hardmask has a wetting angle greater than or equal to about 60°.

17. The method of claim 15, wherein the initial hardmask film is formed to a thickness in the range of about 5 nm to about 20 nm.

18. The method of claim 15, wherein the treatment plasma has a pressure in the range of about 1 Torr to about 5 Torr, a power in the range of about 50 W to about 200 W and exposure occurs for a time in the range of about 2 seconds to about 10 seconds.

19. The method of claim 15, wherein the plasma treatment has a silane compound to inert gas ratio in the range of about 1:1000 to about 2:10.

20. A method of forming a hardmask, the method comprising:
positioning a substrate in a physical vapor deposition chamber;
depositing in the range of about 5 nm to about 20 nm of an initial hardmask film on the substrate by physical vapor deposition, the initial hardmask film comprises one or more of AlO, SiN, a-Si, SiOC, SiON, AlON or AlN; and
moving the substrate from the physical vapor deposition chamber to a chemical vapor deposition chamber; and
exposing the initial hardmask film to a treatment plasma to form the hardmask in the chemical vapor deposition chamber, the treatment plasma comprising a silane compound and an inert gas in a ratio of about 0.1 to about 20% on an atomic basis, a pressure in the range of about 1 Torr to about 5 Torr, a power in the range of about 50 W to about 200 W for a time in the range of about 2 second to about 10 seconds,
wherein the hardmask has a wetting angle greater than or equal to about 60°.
